(19) United States
(12) Patent Application Publication
(10) Pub. No.: US 2024/0063049 A1
(43) Pub. Date: Feb. 22, 2024

(54) SUCTION DEVICE, SUCTION UNIT, SUCTION METHOD, AND COMPUTER-READABLE RECORDING MEDIUM

(71) Applicant: SHINKAWA LTD., Tokyo (JP)

(72) Inventor: Yuji EGUCHI, Tokyo (JP)

(73) Assignee: SHINKAWA LTD., Tokyo (JP)

(21) Appl. No.: 18/270,732

(22) PCT Filed: Mar. 16, 2021
(86) PCT No.: PCT/JP2021/010507

§ 371 Date: Jul. 3, 2023

(51) Int. Cl. H01L 21/683; H01L 21/677

(52) U.S. Cl. CPC H01L 21/6838; H01L 21/67721

(57) ABSTRACT

A suction device, a suction unit, a suction method, and a computer-readable recording medium are provided. The suction device according to the present invention includes: a suction head; a movement control unit that causes the suction head to move between a first position for suction of an electronic component housed in a recess of a housing member and a second position further separated from the electronic component than the first position; a suction control unit that causes suction of the electronic component to the suction head when the suction head is located at the first position. When located at the first position, the suction head has a contact portion that comes into contact with a first surface on an outer side of a region where the recess in the housing member is opened.

### TECHNICAL FIELD

The present invention relates to a suction device, a suction unit, a suction method, and a program.

### RELATED ART

Conventionally, a pick-up tool is widely known as a suction device for suction of a semiconductor chip. For example, Patent Literature 1 discloses a pick-up tool that has a plurality of protrusions on the end surface for suction of the semiconductor chip, and that reduce the contact region with the semiconductor chip to suppress the generation of static electricity, thereby preventing the semiconductor chip from being damaged by static electricity.

### CITATION LIST

### Patent Literature

[Patent Literature 1] JP-2020-53457

### SUMMARY OF INVENTION

### Problem to be Solved

However, in the conventional technology, the semiconductor chip may be damaged due to the load acting on the semiconductor chip from the pick-up tool upon suction of the semiconductor chip, there was a problem that a complicated load control was required for the pick-up tool.

Moreover, these problems are not limited to semiconductor chips, but are generally common to electronic components.

The present invention has been made to solve such problems, and provides a suction device, a suction unit, a suction method, and a program capable of suppressing, through simple control, damage to an electronic component upon suction of the electronic component.

### Solution to Problem

A suction device according to a first aspect of the present invention includes a suction head; a movement control unit that causes the suction head to move between a first position for suction of an electronic component housed in a recess of a housing member and a second position further separated from the electronic component than the first position; a suction control unit that causes suction of the electronic component to the suction head when the suction head is located at the first position. When located at the first position, the suction head has a contact portion that comes into contact with a first surface on an outer side of a region where the recess in the housing member is opened.

Further, a suction unit according to a second aspect of the present invention includes a suction head; a housing member having a recess for housing an electronic component; a movement control unit that causes the suction head to move between a first position for suction of the electronic component housed in the recess of the housing member and a second position further separated from the electronic component than the first position; and a suction control unit that causes suction of the electronic component to the suction head when the suction head is located at the first position. When located at the first position, the suction head has a contact portion that comes into contact with a first surface on an outer side of a region where here the recess in the housing is opened.

Further, a suction method according to a third aspect of the present invention includes a step of causing a suction head to move to a first position for suction of an electronic component housed in a recess of a housing member and causing a contact portion of the suction head to come into contact with a first surface on an outer side of a region where the recess in the housing member is opened; and a step of causing suction of the electronic component to the suction head when the suction head is located at the first position.

Further, a program according to a fourth aspect of the present invention causes a computer to: execute a processing of causing a suction head to move to a first position for suction of an electronic component housed in a recess of a housing member and causing a contact portion of the suction head to come into contact with a first surface on an outer side of a region where the recess in the housing member is opened; and a processing of causing suction of the electronic component to the suction head when the suction head is located at the first position.

### Effects of Invention

According to the present invention, it is possible to, through simple control, suppress damage to an electronic component upon suction of the electronic component.

### BRIEF DESCRIPTION OF DRAWINGS

FIG. 1 is a perspective view schematically showing main parts of a suction unit according to this embodiment.

FIG. 2 is a side view schematically showing mains part of a suction unit according to this embodiment.

FIG. 3 is a plan view schematically showing a positional relationship between a carrier tape and a suction head in a suction unit according to this embodiment.

FIG. 4 is a system configuration view of a suction unit.

FIG. 5 is a flow chart showing a processing procedure of an arithmetic processing unit.

FIG. 6 is a timing chart showing a series of signal processing of a suction unit according to this embodiment.

FIG. 7 is a view showing an operation of a suction unit according to this embodiment.

FIG. 8 is a plan view schematically showing a positional relationship between a carrier tape and a suction head in a suction unit according to another embodiment.

### DESCRIPTION OF EMBODIMENTS

Hereinafter, the present invention will be described through embodiments of the invention, but the invention according to the scope of claims is not limited to the following embodiments. Moreover, not all the configurations described in the embodiments are essential as means for solving the problems.

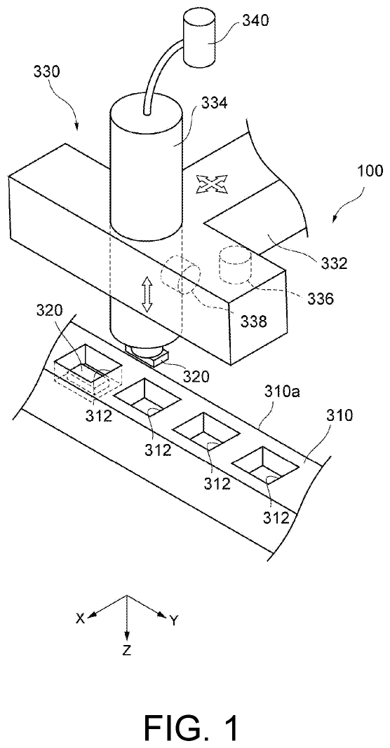

As shown in FIG. 1, a suction unit 100 suctions and picks up a semiconductor chip 320, which is an example of an electronic component housed in a carrier tape 310, by a pick-up tool 330, and places and adheres the semiconductor chip 320 on a substrate. The carrier tape 310 is an example of a housing member, and the pick-up tool 330 is an example of a suction device. The carrier tape 310 has a thin plate shape, and its upper surface is a plane along a plane defined by the X-axis and the Y-axis. A plurality of recesses 312 are formed on the upper surface of the carrier tape 310. The plurality of recesses 312 have rectangular openings and are spaced apart in the Y-axis direction. Each of the recesses 312 houses one semiconductor chip 320.

The pick-up tool 330 includes, for example, a holding unit 332 and a suction head 334. The holding unit 332 holds the suction head 334 and may be moved in a planar direction by a moving mechanism 336. A planar direction is a direction along a plane defined by the X-axis and the Y-axis.

The suction head 334 has a cylindrical shape. The suction head 334 may be moved in the height direction by a lifting mechanism 338. The height direction is the Z-axis direction orthogonal to the planar direction. The suction head 334 suctions the semiconductor chip 320 housed in the recess 312 of the carrier tape 310 by a suction mechanism 340. The suction mechanism 340 is composed of, for example, a suction pump. The suction head 334 picks up the semiconductor chip 320 from the carrier tape 310 by moving upward while suctioning the semiconductor chip 320.

After that, when the pick-up tool 330 places and adheres the semiconductor chip 320 to the substrate, the suction unit 100 moves the carrier tape 310 in the Y-axis direction to a position where the recess 312 and the suction head 334 adjacent in the Y-axis direction face each other in the height direction. Then, the suction unit 100 starts a processing of suction of the semiconductor chip 320 housed in the adjacent recess 312.

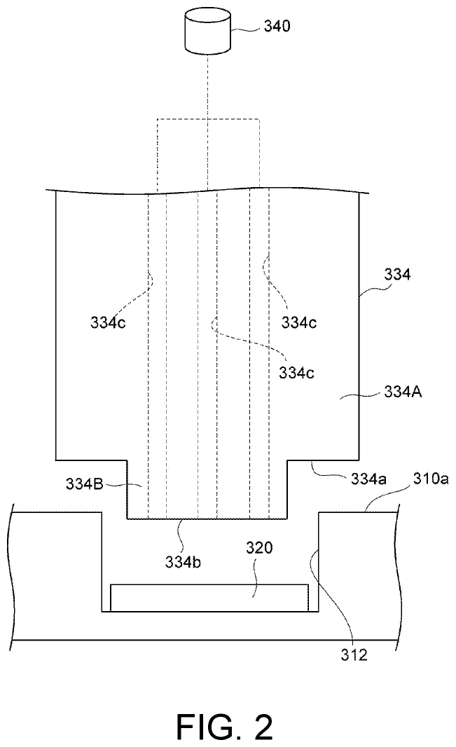

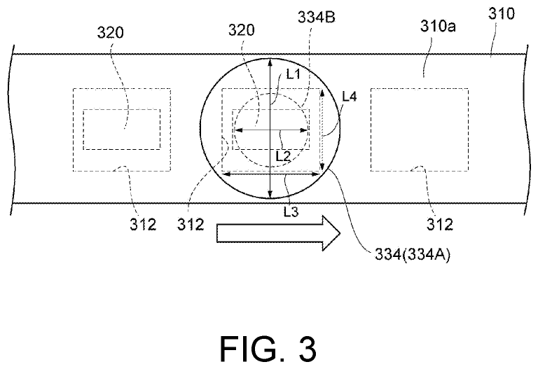

As shown in FIGS. 2 and 3, the suction head 334 includes a cylindrical large-diameter portion 334A and a cylindrical small-diameter portion 334B provided below the large-diameter portion 334A and having an outer diameter smaller than that of the large-diameter portion 334A. When the outer diameter of the large-diameter portion 334A is L1, the outer diameter of the small-diameter portion 334B is L2, the length of the long side of the recess 312 of the carrier tape 310 is L3, and the length of the short side of the recess 312 of the carrier tape 310 is L4, the relational expression of L2<L4<L3<L1 is satisfied. The center position of the large-diameter portion 334A of the suction head 334 and the center position of the recess 312 of the carrier tape 310 overlap in plan view. Moreover, when the suction head 334 reaches a first position, a lower end surface 334a of the large-diameter portion 334A of the suction head 334 comes into contact with an upper surface 310a of the carrier tape 310 on an outer side of a region where the recess 312 is opened. The upper surface 310a of the carrier tape 310 is an example of a first surface. The lower end surface 334a of the large-diameter portion 334A of the suction head 334 is an example of a contact portion. The lower end surface 334a of the large-diameter portion 334A of the suction head 334 comes into contact with the upper surface 310a of the carrier tape 310 while surrounding the recess 312. A plurality of air flow paths 334c are formed through the suction head 334 in the height direction. Each of the plurality of air flow paths 334c has a first end connected to the suction mechanism 340 and a second end opening on a lower end surface 334b of the small-diameter portion 334B of the suction head 334.

Next, the control configuration of the suction unit 100 will be described.

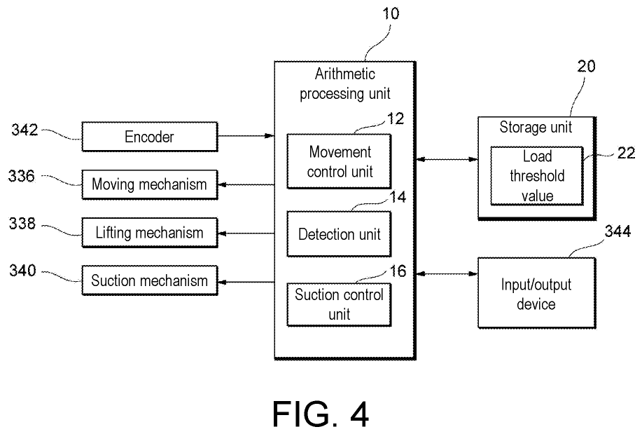

As shown in FIG. 4, the suction unit 100 includes, for example, an arithmetic processing unit 10, a storage unit 20, the moving mechanism 336, the lifting mechanism 338, the suction mechanism 340, an encoder 342, and an input/output device 344. The arithmetic processing unit 10 is a processor (CPU: Central Processing Unit) that executes control of the suction unit 100 and execution processing of a program. The processor may be configured to cooperate with an arithmetic processing chip such as an ASIC (Application Specific Integrated Circuit) or a GPU (Graphics Processing Unit). The arithmetic processing unit 10 reads out a suction control program stored in the storage unit 20 and executes various processings related to suction control.

The storage unit 20 is a non-volatile storage medium, and is configured by, for example, an HDD (Hard Disk Drive). The storage unit 20 stores various parameter values, functions, lookup tables, etc. used for control and calculation, in addition to programs for executing control and processing of the suction unit 100. A load threshold value 22 is an example of a parameter value used for control and calculation.

The moving mechanism 336 moves the suction head 334 in the X direction and the Y direction based on the drive signal output from the arithmetic processing unit 10.

The lifting mechanism 338 moves the suction head 334 in the Z direction based on the drive signal output from the arithmetic processing unit 10. The arithmetic processing unit 10 generates a drive signal based on the positional information of the suction head 334 in the Z-direction measured by the encoder 342 and outputs the generated drive signal to the lifting mechanism 338.

The suction mechanism 340 causes the suction head 334 to suction the semiconductor chip 320 housed in the recess 312 of the carrier tape 310 based on the drive signal output from the arithmetic processing unit 10.

The input/output device 344 includes, for example, a keyboard, mouse, and display monitor, and is a device that accepts menu operations by the user and presents information to the user. The input/output device 344 outputs a signal indicating an instruction to start suction control to the arithmetic processing unit 10, for example, based on a user's operation.

The arithmetic processing unit 10 also plays a role as a functional arithmetic unit that executes various kinds of arithmetic according to the processing instructed by the suction control program. The arithmetic processing unit 10 includes, for example, a movement control unit 12, a detection unit 14, and a suction control unit 16.

The movement control unit 12 causes the suction head 334 to move between the first position for suction of the semiconductor chip 320 housed in the recess 312 of the carrier tape 310 and a second position further separated from the semiconductor chip 320 than the first position. The movement control unit 12 causes the suction head 334 to move from the second position toward the first position, for example, when receiving an instruction to start suction control from the user through the input/output device 344.

The detection unit 14 detects that the lower end surface 334a of the large-diameter portion 334A of the suction head 334 is in contact with the upper surface 310a of the carrier tape 310. For example, based on the position of the suction head 334 measured by the encoder 342 and the drive signal output from the arithmetic processing unit 10 to the lifting mechanism 338, the detection unit 14 calculates the magnitude of the load acting on the carrier tape 310 from the suction head 334. Then, when the calculated magnitude of the load reaches the load threshold value 22, the detection unit 14 detects that the lower end surface 334a of the large-diameter portion 334A of the suction head 334 is in contact with the upper surface 310a of the carrier tape 310.

The suction control unit 16 causes the suction head 334 to suction the semiconductor chip 320 when the suction head 334 is located at the first position. For example, the suction control unit 16 causes the suction head 334 to suction the semiconductor chip 320 on condition that it is detected by the detection unit 14 that the lower end surface 334A of the large-diameter portion 334A of the suction head 334 is in contact with the upper surface 310a of the carrier tape 310.

Next, the suction control executed by the suction unit 100 according to this embodiment will be described.

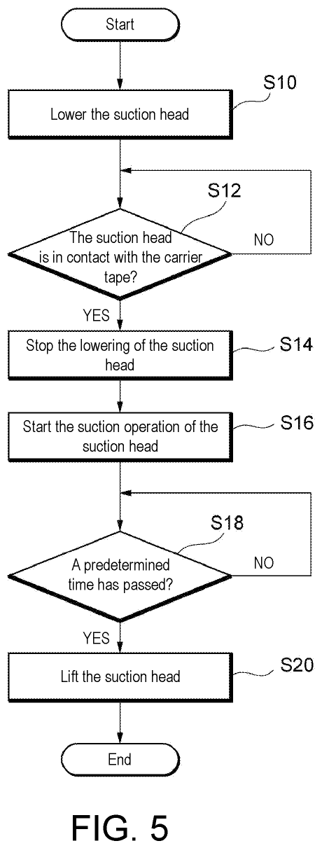

FIG. 5 is a flow chart showing a processing procedure of the arithmetic processing unit 10. The flow chart shown in FIG. 5 is executed, for example, when a user's instruction to start suction control is received through the input/output device 344.

As shown in FIG. 5, the arithmetic processing unit 10 first outputs a drive signal to the lifting mechanism 338 to lower the suction head 334 (step S10).

Next, based on the position of the suction head 334 measured by the encoder 342 and the drive signal output to the lifting mechanism 338, the arithmetic processing unit 10 determines whether or not the suction head 334 is in contact with the carrier tape 310 (step S12). When the arithmetic processing unit 10 determines that the suction head 334 is in contact with the carrier tape 310 (step S12=YES), it stops outputting the drive signal to the lifting mechanism 338 to stop the lowering of the suction head 334 (step S14).

Next, the arithmetic processing unit 10 outputs a drive signal to the suction mechanism 340 to start the suction operation of the suction head 334 (step S16). Then, the arithmetic processing unit 10 determines whether or not a predetermined time has passed since the suction head 334 started the suction operation (step S18). When the arithmetic processing unit 10 determines that the predetermined time has passed since the suction operation of the suction head 334 started (step S18=YES), it outputs a drive signal to the lifting mechanism 338 to lift the suction head 334. (Step S20).

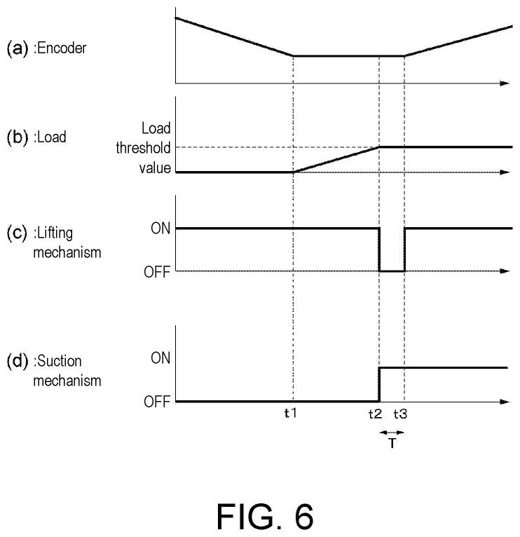

FIG. 6 is a timing chart showing the flow of a series of processing of the suction unit 100.

As shown in (a) of FIG. 6, when the suction control is started, in the suction unit 100, the position of the suction head 334 measured by the encoder 342 moves downward as the suction head 334 is lowered by the lifting mechanism 338. Then, at time t1, when the suction head 334 comes into contact with the carrier tape 310, the measurement position of the suction head 334 is maintained.

In this case, as shown in (b) of FIG. 6, when the lowering of the suction head 334 by the lifting mechanism 338 continues, the load acting on the carrier tape 310 from the suction head 334 gradually increases. Then, at time t2, when the load acting on the carrier tape 310 from the suction head 334 reaches the load threshold value, the lowering of the suction head 334 by the lifting mechanism 338 is stopped (see (c) of FIG. 6). Moreover, at time t2, when the load acting on the carrier tape 310 from the suction head 334 reaches the load threshold value, the suction operation of the suction head 334 by the suction mechanism 340 is started (see (d) of FIG. 6).

Then, as shown in (c) of FIG. 6, at time t3, when a predetermined time T has passed since the suction operation of the suction head 334 started, lifting of the suction head 334 by the lifting mechanism 338 is started. Further, as shown in (a) of FIG. 6, at time t3, when the lifting of the suction head by the lifting mechanism 338 is started, the position of the suction head measured by the encoder 342 moves upward. In this case, as shown in (d) of FIG. 6, the suction operation of the suction head 334 by the suction mechanism 340 is maintained.

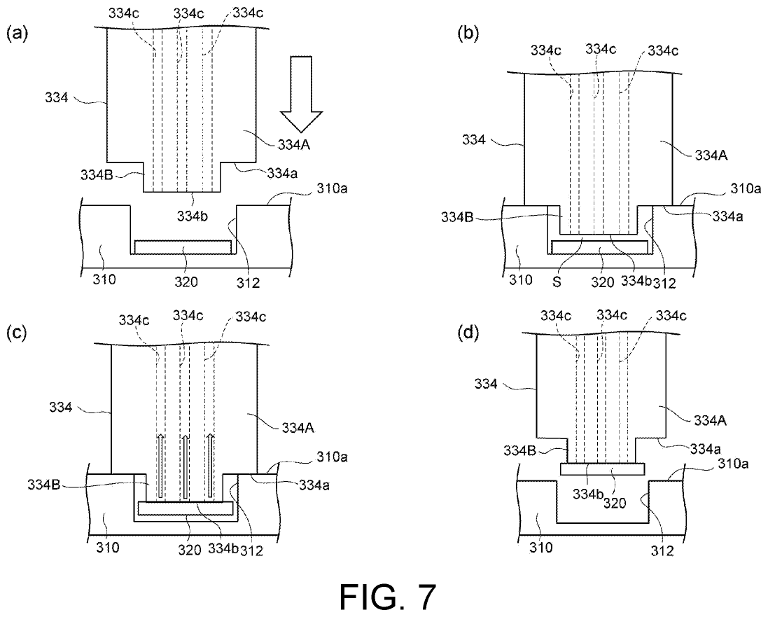

FIG. 7 is a view showing an operation of the suction unit.

As shown in (a) of FIG. 7, when the suction control is started, the suction unit 100 first drives the lifting mechanism 338 to move the suction head 334 downward so as to approach the carrier tape 310. While the lifting mechanism 338 moves the suction head 334 downward, the suction unit 100 controls the load acting on the carrier tape 310 from the suction head 334 based on the position in the height direction of the suction head 334 measured by the encoder 342 and the magnitude of the driving force output from the lifting mechanism 338 to the suction head 334.

Next, as shown in (b) of FIG. 7, when the load acting on the carrier tape 310 from the suction head 334 reaches the load threshold value 22, the suction unit 100 stops driving the lifting mechanism 338 to stop the downward movement of the suction head 334. In this case, the lower end surface 334a of the large-diameter portion 334A of the suction head 334 is in contact with the upper surface 310a of the carrier tape 310. Moreover, a gap S is interposed between the lower end surface 334a of the large-diameter portion 334A of the suction head 334 and the semiconductor chip 320.

Next, as shown in (c) of FIG. 7, the suction unit 100 drives the suction mechanism 340 to start the suction operation of the suction head 334. The suction unit 100 operates the suction mechanism 340 with the suction head 334 sealing the recess 312 of the carrier tape 310, thereby sucking air from the recess 312 of the carrier tape 310 through the plurality of air flow paths 334c. As a result, the suction unit 100 suctions the semiconductor chip 320 housed in the recess 312 of the carrier tape 310 to the lower end surface 334b of the small-diameter portion 334B of the suction head 334 with negative pressure.

Next, as shown in (d) of FIG. 7, the suction unit 100 drives the lifting mechanism 338 to move the suction head 334 upward while continuing to drive the suction mechanism 340 to maintain the suction operation of the suction head 334. As a result, the suction unit 100 picks up the semiconductor chip 320 housed in the recess 312 of the carrier tape 310 by the suction head 334.

Moreover, the above embodiment may be implemented in the following forms.

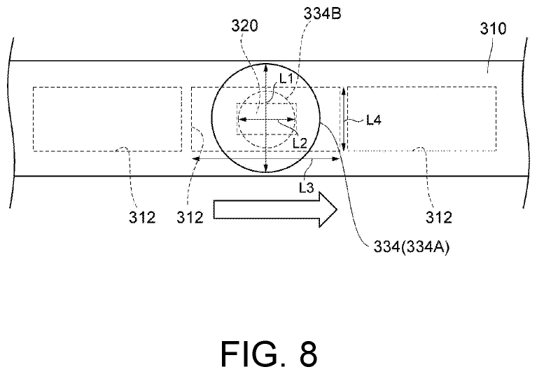

In the above embodiment, as shown in FIG. 8, the relational expression L2<L4<L1<L3 may be satisfied in the suction unit 100 when the outer diameter of the large-diameter portion 334A is L1, the outer diameter of the small-diameter portion 334B is L2, the length of the long side of the recess 312 of the carrier tape 310 is L3, and the length of the short side of the recess 312 of the carrier tape 310 is L4. In the example shown in this diagram, the center position of the large-diameter portion 334A of the suction head 334 and the center position of the recess 312 of the carrier tape 310 overlap in plan view. In this case, when the suction head 334 reaches the first position, the lower end surface 334a of the large-diameter portion 334A of the suction head 334 comes into contact the upper surface 310a of the carrier tape 310 on at least two opposing sides of the recess 312.

In the above embodiment, the shape of the suction head 334 does not necessarily have to be cylindrical, and other shapes such as a prismatic shape may be adopted.

In the above embodiment, the longitudinal direction of the carrier tape 310 may be aligned with the longitudinal direction of the recesses 312 and the lateral direction of the carrier tape 310 may be aligned with the lateral direction of the recesses 312.

In the above embodiment, the suction head 334 may contact the upper surface 310a of the carrier tape 310 on at least two adjacent sides of the recess 312. In short, it is sufficient that the suction head 334 comes into contact with a part of the upper surface 310a of the carrier tape 310 on an outer side of a region where the recess 312 is opened.

In the above embodiment, when the suction head 334 is located at the first position, there may be no gap interposed between the suction head 334 and the semiconductor chip 320.

In the above-described embodiment, the pick-up tool 330 may include a sensor that detects that the suction head 334 is in contact with the upper surface 310a of the carrier tape 310 on an outer side of a region where the recess 312 is opened.

As described above, the case where a suction device according to this embodiment is applied to a pick-up tool has been described as an example, but the suction device according to this embodiment is not limited to a pick-up tool, and may be applied to, for example, a die bonder or a flip chip bonder.

### REFERENCE SIGNS LIST

10 Arithmetic processing unit
12 Movement control unit
14 Detector
16 Suction control unit
20 Storage unit
22 Load threshold value
100 Suction unit
310 Carrier tape
310a Upper surface
312 Recess
320 Semiconductor chip
330 Pick-up tool
332 Holding unit
334 Suction head
334A Large-diameter portion
334B Small-diameter portion
334a Lower end surface
334b Lower end surface
334c Air flow path
336 Moving Mechanism
338 Lifting mechanism
340 Suction mechanism
342 Encoder
344 Input/output device
S Gap

1. A suction device, comprising:
a suction head;
a movement control unit that causes the suction head to move between a first position for suction of an electronic component housed in a recess of a housing member and a second position further separated from the electronic component than the first position;
a suction control unit that causes suction of the electronic component to the suction head when the suction head is located at the first position,
wherein when located at the first position, the suction head has a contact portion that comes into contact with a first surface on an outer side of a region where the recess in the housing member is opened, and a small-diameter portion that protrudes from the contact portion when the contact portion is in contact with the first surface of the housing member and suctions and holds the electronic component from the recess;
a detection unit that detects a load acting on the suction head based on a height position of the suction head measured by an encoder and a driving force output from the movement control unit to the suction head and detects that the contact portion is in contact with the first surface of the housing member according to a change in the load is further comprised; and
the suction control unit stops movement of the suction head on condition that it is detected by the detection unit that the contact portion of the suction head is in contact with the first surface of the housing member and causes the suction of the electronic component to the suction head.

2. (canceled)

3. The suction device according to claim 1,
wherein a gap is interposed between the suction head and the electronic component when the suction head is located at the first position.

4. The suction device according to claim 1,
wherein the contact portion comes into contact with the first surface of the housing member on at least two opposing sides of the recess when the suction head is located at the first position.

5. The suction device according to claim 1,
wherein the contact portion comes into contact with the first surface of the housing member while surrounding the recess when the suction head is located at the first position.

6. A suction unit, comprising:
a suction head;
a housing member having a recess for housing an electronic component;
a movement control unit that causes the suction head to move between a first position for suction of the electronic component housed in the recess of the housing member and a second position further separated from the electronic component than the first position; and
a suction control unit that causes suction of the electronic component to the suction head when the suction head is located at the first position,
wherein when located at the first position, the suction head has a contact portion that comes into contact with a first surface on an outer side of a region where the recess in the housing member is opened, and a small-diameter portion that protrudes from the contact portion when the contact portion is in contact with the first surface of the housing member and suctions and holds the electronic component from the recess;
a detection unit that detects a load acting on the suction head based on a height position of the suction head measured by an encoder and a driving force output from the movement control unit to the suction head and detects that the contact portion is in contact with the first surface of the housing member according to a change in the load is further comprised; and
the suction control unit stops movement of the suction head on condition that it is detected by the detection unit that the contact portion of the suction head is in contact with the first surface of the housing member and causes the suction of the electronic component to the suction head.

7. A suction method, comprising:
a step of causing a suction head to move to a first position for suction of an electronic component housed in a recess of a housing member and causing a contact portion of the suction head to come into contact with a first surface on an outer side of a region where the recess in the housing member is opened;
a step of detecting a load acting on the suction head based on a height position of the suction head measured by an encoder and a driving force output from a movement control unit to the suction head and detecting that the contact portion is in contact with the first surface of the housing member according to a change in the load; and
a step of stopping movement of the suction head on condition that it is detected that the contact portion of the suction head is in contact with the first surface of the housing member and causing suction of the electronic component to a small-diameter portion of the suction head, which protrudes from the contact portion when the contact portion is in contact with the first surface of the housing member, when the suction head is located at the first position.

8. A computer-readable recording medium, causing a computer to execute:
a processing of causing a suction head to move to a first position for suction of an electronic component housed in a recess of a housing member and causing a contact portion of the suction head to come into contact with a first surface on an outer side of a region where the recess in the housing member is opened;
a processing of detecting a load acting on the suction head based on a height position of the suction head measured by an encoder and a driving force output from a movement control unit to the suction head and detecting that the contact portion is in contact with the first surface of the housing member according to a change in the load; and
a processing of stopping movement of the suction head on condition that it is detected that the contact portion of the suction head is in contact with the first surface of the housing member and causing suction of the electronic component to a small-diameter portion of the suction head, which protrudes from the contact portion when the contact portion is in contact with the first surface of the housing member, when the suction head is located at the first position.

9. The suction device according to claim 3,
wherein the contact portion comes into contact with the first surface of the housing member on at least two opposing sides of the recess when the suction head is located at the first position.

10. The suction device according to claim 3,
wherein the contact portion comes into contact with the first surface of the housing member while surrounding the recess when the suction head is located at the first position.

11. The suction device according to claim 4,
wherein the contact portion comes into contact with the first surface of the housing member while surrounding the recess when the suction head is located at the first position.
